(19) United States
(12) Patent Application Publication
(10) Pub. No.: US 2024/0421203 A1
(43) Pub. Date: Dec. 19, 2024

(54) SEMICONDUCTOR DEVICE

(71) Applicant: ROHM CO., LTD., Kyoto-shi (JP)

(72) Inventors: Shojiro KATO, Kyoto-shi (JP); Keita OKAMOTO, Kyoto-shi (JP); Shuntaro TAKAHASHI, Kyoto-shi (JP)

(73) Assignee: ROHM CO., LTD., Kyoto-shi (JP)

(21) Appl. No.: 18/820,307

(22) Filed: Aug. 30, 2024

Related U.S. Application Data
(63) Continuation of application No. PCT/JP2023/009717, filed on Mar. 13, 2023.

(30) Foreign Application Priority Data
Mar. 31, 2022 (JP) 2022-061320

(51) Int. Cl. H01L 29/417; H01L 23/538; H01L 27/02; H01L 27/088

(52) U.S. Cl. CPC H01L 29/41766; H01L 23/5386; H01L 27/0207; H01L 27/088

(57) ABSTRACT

A semiconductor device includes an insulated gate type first transistor that is formed at a semiconductor chip, an insulated gate type second transistor that is formed at the semiconductor chip, and a control wiring that transmits a control signal controlling the first transistor and the second transistor to reach an ON state during a normal operation and controlling the first transistor to reach an OFF state and the second transistor to reach an ON state during an active clamp operation.

### CROSS-REFERENCE TO RELATED APPLICATIONS

The present application is a continuation application of PCT Application No. PCT/JP2023/009717, filed on Mar. 13, 2023, which corresponds to Japanese Patent Application No. 2022-061320 filed on Mar. 31, 2022 with the Japan Patent Office, and the entire disclosure of these applications is incorporated herein by reference.

### TECHNICAL FIELD

The present disclosure relates to a semiconductor device.

### BACKGROUND ART

For example, Japanese Patent Application Publication No. 2015-70193 discloses a planar gate type semiconductor device as an example of a semiconductor device including an insulated gate type transistor. This semiconductor device includes a semiconductor layer having a principal surface, a gate insulation layer formed on the principal surface, a gate electrode formed on the gate insulation layer, and a channel facing the gate electrode across the gate insulation layer in a surficial portion of the semiconductor layer.

### BRIEF DESCRIPTION OF DRAWINGS

FIG. 1 is a schematic plan view of a semiconductor device according to a preferred embodiment of the present disclosure.

FIG. 2 is a block circuit diagram showing an electric structure of the semiconductor device of FIG. 1.

FIG. 3 is a circuit diagram shown to describe a normal operation and an active clamp operation of the semiconductor device of FIG. 1.

FIG. 4 is a waveform chart of a main electric signal applied to the circuit diagram of FIG. 3.

FIG. 5 is a schematic plan view shown by enlarging a part of an element region of FIG. 1.

FIG. 6 is a schematic perspective view showing a wiring structure of a transistor of FIG. 5.

FIG. 7 is a view showing a cross section of line VII-VII of FIG. 5.

FIG. 8 is a view shown to describe a normal operation according to a controlling example of the semiconductor device.

FIG. 9 is a view shown to describe an active clamp operation according to a controlling example of the semiconductor device.

FIG. 10 is a view showing a flow of an electric current in the semiconductor device.

FIG. 11 is a block circuit diagram showing the semiconductor device (=an electric structure to perform the Half-ON control of a power MISFET during an active clamp operation if the semiconductor device is a low-side switch).

FIG. 12 is an equivalent circuit diagram in which the power MISFET of FIG. 11 is represented as a first transistor and a second transistor.

FIG. 13 is a circuit diagram showing a configuration example of a gate control circuit and an active clamp circuit in FIG. 11.

FIG. 14 is a timing chart showing an aspect in which the Half-ON control of a power MISFET is performed during an active clamp operation if the semiconductor device is a low-side switch.

### DESCRIPTION OF EMBODIMENTS

Next, a preferred embodiment of the present disclosure will be described in detail with reference to the accompanying drawings.

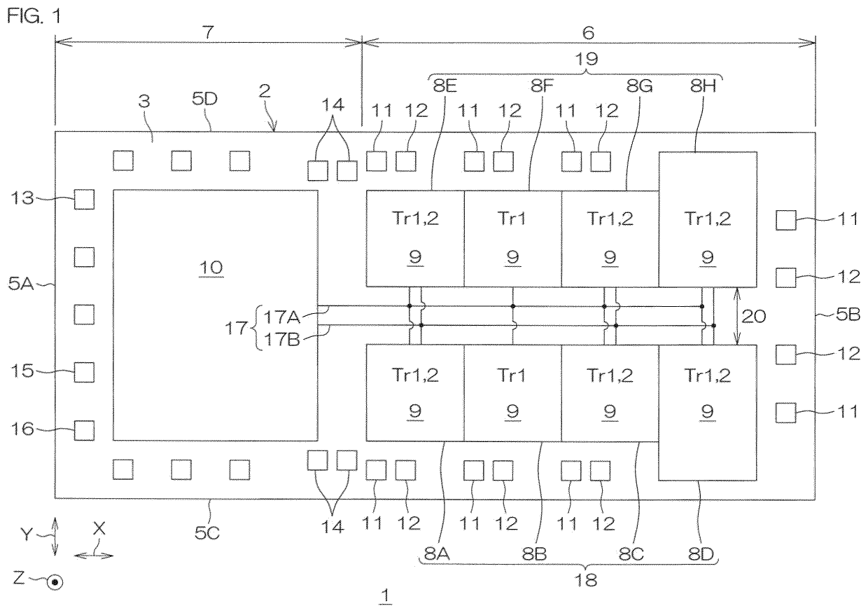

FIG. 1 is a schematic plan view of a semiconductor device according to the preferred embodiment of the present disclosure. Although a form example in which a semiconductor device 1 is a switching device is hereinafter described, the semiconductor device 1 is not limited to the high-side switching device. The semiconductor device 1 can be provided also as a low-side switching device by adjusting electrical connection modes and functions of various structures.

Referring to FIG. 1, the semiconductor device 1 includes a semiconductor chip 2. The semiconductor chip 2 includes silicon. The semiconductor chip 2 is formed in a rectangular parallelepiped shape. The semiconductor chip 2 has a first principal surface 3 on one side, a second principal surface 4 on the other side, and end surfaces 5A, 5B, 5C, and 5D connecting the first and second principal surfaces 3 and 4 together.

The first and second main surfaces 3 and 4 are each formed in a quadrangular shape (in this preferred embodiment, rectangular shape) in a plan view seen from their normal directions Z (hereinafter, referred to simply as a “plan view”). The first end surface 5A and the second end surface 5B extend along a first direction X, and face each other in a second direction Y intersecting the first direction X. The third end surface 5C and the fourth end surface 5D extend along the second direction Y, and face each other in the first direction X. In detail, the second direction Y perpendicularly intersects the first direction X. The first and second end surfaces 5A and 5B form an end surface in a lateral direction of the semiconductor chip 2 having the rectangular shape in a plan view, and the third and fourth end surfaces 5C and 5D form an end surface in a longitudinal direction of the semiconductor chip 2.

An output region 6 and an input region 7 are defined in the semiconductor chip 2. The output region 6 is defined in a region on the second end surface 5B side. The input region 7 is defined in a region on the first end surface 5A side. An area S_{OUT} of the output region 6 is equal to or more than an area S_{IN} of the input region 7 in a plan view (S_{IN}≤S_{OUT}).

A ratio S_{OUT}/S_{IN} of the area S_{OUT} to the area S_{IN} may be not less than 1 and not more than 10 (1≤S_{OUT}/S_{IN}≤10). The ratio S_{OUT}/S_{IN} may be not less than 1 and not more than 2, not less than 2 and not more than 4, not less than 4 and not more than 6, not less than 6 and not more than 8, or not less than 8 and not more than 10. The planar shape of the input region 7 and the planar shape of the output region 6 are arbitrary, and are not limited to a specific shape. Of course, the ratio S_{OUT}/S_{IN} may be more than 0 and less than 1.

The output region 6 includes a plurality of element regions 8A to 8H in which a power MISFET (Metal Insulator Semiconductor Field Effect Transistor) 9 that is an example of an insulated gate type transistor is formed. The power MISFET 9 includes a gate, a drain, and a source. In this preferred embodiment, the element regions 8A to 8H include a first element region 8A, a second element region 8B, a third element region 8C, a fourth element region 8D, a fifth element region 8E, a sixth element region 8F, a seventh element region 8G, and an eighth element region 8H. The element regions 8A to 8H are arrayed in a horizontal direction along the first principal surface 3.

More specifically, the first element region 8A to the fourth element region 8D are arrayed in a direction of receding from the input region 7 toward the second end surface 5B along the third end surface 5C. The first element region 8A to the fourth element region 8D may be collectively referred to as a first element region group 18. The fifth element region 8E to the eighth element region 8H are arrayed in the direction of receding from the input region 7 toward the second end surface 5B along the fourth end surface 5D. The fifth element region 8E to the eighth element region 8H may be collectively referred to as a second element region group 19. The first element region group 18 and the second element region group 19 are each formed in a substantially rectangular shape that is longitudinal in the first direction X.

The first element region group 18 is arranged on the third end surface 5C side with respect to a central portion of the second direction Y, and the second element region group 19 is arranged on the fourth end surface 5D side. A wiring region 20 that extends from the input region 7 toward the second end surface 5B is formed between the first element region group 18 and the second element region group 19.

As thus described, the element regions 8A to 8H independent of each other are formed in the single semiconductor chip 2, and therefore it is possible to use the semiconductor device 1 with a multi-channel (in this preferred embodiment, eight channels). For example, the element regions 8A to 8D of the first element region group 18 may be used as a high-side switch, and the element regions 8E to 8H of the second element region group 19 may be used as a low-side switch. At least either one of a first transistor Tr1 and a second transistor Tr2 that are distinguished from each other by the structure of the power MISFET 9 is formed in each of the element regions 8A to 8H.

The input region 7 includes a control IC (Integrated Circuit) 10 that is an example of a control circuit. The control IC 10 includes a plurality of kinds of functional circuits that fulfill various functions. The functional circuits include a circuit that generates a gate control signal that drives and controls the power MISFET 9 on the basis of an electric signal from the outside. The control IC 10 forms a so-called IPD (Intelligent Power Device) together with the power MISFET 9. The IPD is referred to also as an IPM (Intelligent Power Module).

The input region 7 is electrically insulated from the output region 6 by means of a region separation structure (not shown). The region separation structure may have a trench insulation structure in which an insulator is buried into a trench although a detailed description is omitted.

A plurality of (in this preferred embodiment, six) electrodes 11, 12, 13, 14, 15, and 16 are formed on the semiconductor chip 2. The electrodes 11 to 16 are formed as terminal electrodes that are connected to the outside by means of lead wires, etc. (for example, bonding wires). The number, the arrangement, and the planar shape of the electrodes 11 to 16 are arbitrary, and are not limited to the form shown in FIG. 1.

The number, the arrangement, and the planar shape of the electrodes 11 to 16 are adjusted in accordance with the specifications of the power MISFET 9 and the specifications of the control IC 10. In this preferred embodiment, the electrodes 11 to 16 include a drain electrode 11 (power electrode), a source electrode 12 (output electrode), an input electrode 13, a reference voltage electrode 14, an ENABLE electrode 15, and a SENSE electrode 16.

The drain electrode 11 is formed on the output region 6 in the first principal surface 3, and is provided in each of the element regions 8A to 8H. The drain electrode 11 transmits a power supply voltage VB to the drain of the power MISFET 9 and to various circuits of the control IC 10.

The source electrode 12 is formed on the output region 6 in the first principal surface 3, and is provided in each of the element regions 8A to 8H. The source electrode 12 is electrically connected to the source of the power MISFET 9. The source electrode 12 transmits an electric signal generated by the power MISFET 9 to the outside.

The drain electrode 11 and the source electrode 12 are arranged between each of the element regions 8A to 8D and the third end surface 5C or the second end surfaces 5B near the first element region group 18. The drain electrode 11 and the source electrode 12 are adjacent to each other. The drain electrode 11 and the source electrode 12 are arranged between each of the element regions 8E to 8H and the fourth end surface 5D or the second end surfaces 5B near the second element region group 19. The drain electrode 11 and the source electrode 12 are adjacent to each other.

The input electrode 13, the reference voltage electrode 14, the ENABLE electrode 15, and the SENSE electrode 16 are each formed on the input region 7 in the first principal surface 3. The input electrode 13 transmits an input voltage by which the control IC 10 is driven.

The reference voltage electrode 14 transmits a reference voltage (for example, ground voltage) to the control IC 10. The reference voltage electrode 14 is formed at a boundary portion between the input region 7 and the output region 6, and is provided for each of the first element region group 18 and the second element region group 19. The reference voltage electrode 14 is adjacent to the first and fifth element regions 8A and 8E among the element regions of the first and second element region groups 18 and 19 that are closest to the input region 7.

The ENABLE electrode 15 transmits an electric signal by which part or all of the functions of the control IC 10 are enabled or disabled. The SENSE electrode 16 transmits an electric signal that detects the abnormality of the control IC 10.

A gate control wiring 17 that is an example of a control wiring is additionally formed on the semiconductor chip 2. The gate control wiring 17 is selectively routed to the output region 6 and the input region 7. More specifically, the gate control wiring 17 extends from the input region 7 toward the second end surface 5B in the wiring region 20. The gate control wiring 17 branches from the wiring region 20 toward each of the element regions 8A to 8H, and is electrically connected to the gate of the power MISFET 9. Also, the gate control wiring 17 is electrically connected to the control IC 10 in the input region 7.

The gate control wiring 17 transmits a gate control signal generated by the control IC 10 to the gate of the power MISFET 9. The gate control signal includes an ON signal Von and an OFF signal Voff, and controls an ON state and an OFF state of the power MISFET 9.

The ON signal Von is equal to or more than a gate threshold voltage Vth of the power MISFET 9 (Vth<Von). The OFF signal Voff is less than the gate threshold voltage Vth of the power MISFET 9 is (Voff<Vth). The OFF signal Voff may be a reference voltage (for example, ground voltage).

In this preferred embodiment, the gate control wiring 17 includes a first gate control wiring 17A and a second gate control wiring 17B. The first gate control wiring 17A and the second gate control wiring 17B are electrically insulated from each other. The first gate control wiring 17A branches toward the element regions 8A to 8H including the first transistor Tr1, and is connected to the gate of the first transistor Tr1. The second gate control wiring 17B branches toward the element regions 8A, 8C, 8D, 8E, 8G, and 8H including the second transistor Tr2, and is connected to the gate of the second transistor Tr2.

The first gate control wiring 17A and the second gate control wiring 17B transmit mutually same or different gate control signals to the gate of the power MISFET 9. The number, the arrangement, the shape, etc., of the gate control wirings 17 are arbitrary, and are adjusted in accordance with the transmission distance of the gate control signal or the number of the gate control signals to be transmitted.

The drain electrode 11, the source electrode 12, the input electrode 13, the reference voltage electrode 14, the ENABLE electrode 15, the SENSE electrode 16, and the gate control wiring 17 may each include at least type one among nickel, palladium, aluminum, copper, an aluminum alloy, and a copper alloy.

The drain electrode 11, the source electrode 12, the input electrode 13, the reference voltage electrode 14, the ENABLE electrode 15, the SENSE electrode 16, and the gate control wiring 17 may include at least one type among an Al—Si—Cu (aluminum-silicon-copper) alloy, an Al—Si (aluminum-silicon) alloy, and an Al—Cu (aluminum-copper) alloy.

The drain electrode 11, the source electrode 12, the input electrode 13, the reference voltage electrode 14, the ENABLE electrode 15, the SENSE electrode 16, and the gate control wiring 17 may respectively include electrode materials that are the same in kind, or may include electrode materials that are mutually different in kind.

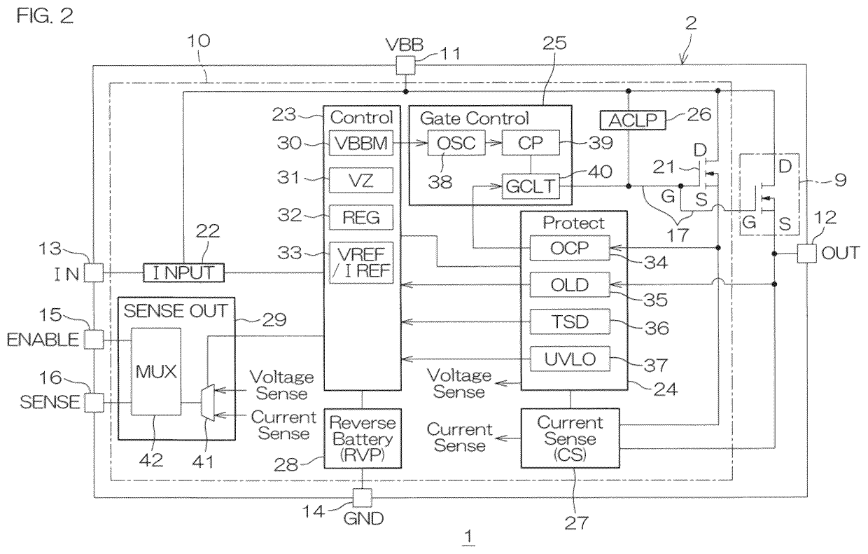

FIG. 2 is a block circuit diagram showing an electric structure of the semiconductor device 1 shown in FIG. 1. A case in which the semiconductor device 1 is mounted on a vehicle will be hereinafter described as an example.

The semiconductor device 1 includes the drain electrode 11, the source electrode 12, the input electrode 13, the reference voltage electrode 14, the ENABLE electrode 15, the SENSE electrode 16, the gate control wiring 17, the power MISFET 9, and the control IC 10.

The drain electrode 11 is connected to a power source. The drain electrode 11 provides the power supply voltage VB to the power MISFET 9 and to the control IC 10. The power supply voltage VB may be not less than 10 V and not more than 20 V. The source electrode 12 is connected to a load.

The input electrode 13 may be connected to an MCU (Micro Controller Unit), a DC/DC converter, an LDO (Low Drop Out), etc. The input electrode 13 provides an input voltage to the control IC 10. The input voltage may be not less than 1 V and not more than 10 V. The reference voltage electrode 14 is connected to a reference voltage wiring. The reference voltage electrode 14 provides a reference voltage to the power MISFET 9 and to the control IC 10.

The ENABLE electrode 15 may be connected to the MCU. An electric signal by which part or all of the functions of the control IC 10 are enabled or disabled is input into the ENABLE electrode 15. The SENSE electrode 16 may be connected to a resistor.

The gate of the power MISFET 9 is connected to the control IC 10 (gate control circuit 25 described later) through the gate control wiring 17. The drain of the power MISFET 9 is connected to the drain electrode 11. The source of the power MISFET 9 is connected to the control IC 10 (a current detection circuit 27 described later) and to the source electrode 12.

The control IC 10 includes a sensor MISFET 21, an input circuit 22, a current-voltage control circuit 23, a protection circuit 24, a gate control circuit 25, an active clamp circuit 26, the current detection circuit 27, a power source reverse connection protection circuit 28, and an abnormality detection circuit 29.

The gate of the sensor MISFET 21 is connected to the gate control circuit 25. The drain of the sensor MISFET 21 is connected to the drain electrode 11. The source of the sensor MISFET 21 is connected to the current detection circuit 27.

The input circuit 22 is connected to the input electrode 13 and to the current-voltage control circuit 23. The input circuit 22 may include a Schmidt trigger circuit. The input circuit 22 shapes the waveform of an electric signal applied to the input electrode 13. A signal generated by the input circuit 22 is input into the current-voltage control circuit 23.

The current-voltage control circuit 23 is connected to the protection circuit 24, to the gate control circuit 25, to the power source reverse connection protection circuit 28, and to the abnormality detection circuit 29. The current-voltage control circuit 23 may include a logic circuit.

The current-voltage control circuit 23 generates various voltages in accordance with an electric signal emitted from the input circuit 22 and an electric signal emitted from the protection circuit 24. In this preferred embodiment, the current-voltage control circuit 23 includes a driving voltage generation circuit 30, a first constant voltage generation circuit 31, a second constant voltage generation circuit 32, and a reference voltage/reference current generation circuit 33.

The driving voltage generation circuit 30 generates a driving voltage to drive the gate control circuit 25. The driving voltage may be set at a value obtained by subtracting a predetermined value from the power supply voltage VB. The driving voltage generation circuit 30 may generate a driving voltage of not less than 5 V and not more than 15 V that is obtained by subtracting 5 V from the power supply voltage VB. The driving voltage is input into the gate control circuit 25.

The first constant voltage generation circuit 31 generates a first constant voltage to drive the protection circuit 24. The first constant voltage generation circuit 31 may include a Zener diode or a regulator circuit (here, Zener diode). The first constant voltage may be not less than 1 V and not more than 5 V. The first constant voltage is input into the protection circuit 24 (in detail, a load-open detection circuit 35 or the like described later).

The second constant voltage generation circuit 32 generates a second constant voltage to drive the protection circuit 24. The second constant voltage generation circuit 32 may include a Zener diode or a regulator circuit (here, regulator circuit). The second constant voltage may be not less than 1 V and not more than 5 V. The second constant voltage is input into the protection circuit 24 (in detail, overheat protection circuit 36 or low voltage malfunction suppressor circuit 37 described later).

The reference voltage/reference current generation circuit 33 generates a reference voltage and a reference current of various circuits. The reference voltage may be not less than 1 V and not more than 5 V. The reference current may be not less than 1 mA and not more than 1 A. The reference voltage and the reference current are input into various circuits. If the various circuits include a comparator, the reference voltage and the reference current may be input into this comparator.

The protection circuit 24 is connected to the current-voltage control circuit 23, to the gate control circuit 25, to the abnormality detection circuit 29, to the source of the power MISFET 9, and to the source of the sensor MISFET 21. The protection circuit 24 includes an overcurrent protection circuit 34, the load-open detection circuit 35, the overheat protection circuit 36, and the low voltage malfunction suppressor circuit 37.

The overcurrent protection circuit 34 protects the power MISFET 9 from an overcurrent. The overcurrent protection circuit 34 is connected to the source of the gate control circuit 25 and to the sensor MISFET 21. The overcurrent protection circuit 34 may include a current monitor circuit. A signal generated by the overcurrent protection circuit 34 is input into the gate control circuit 25 (in detail, a driving signal output circuit 40 described later).

The load-open detection circuit 35 detects a short state or an open state of a load. The load-open detection circuit 35 is connected to the current-voltage control circuit 23 and to the source of the power MISFET 9. A signal generated by the load-open detection circuit 35 is input into the current-voltage control circuit 23.

The overheat protection circuit 36 monitors the temperature of the power MISFET 9, and protects the power MISFET 9 from an excessive rise in temperature. The overheat protection circuit 36 is connected to the current-voltage control circuit 23. The overheat protection circuit 36 may include a temperature sensing device, such as a temperature sensing diode or a thermistor. A signal generated by the overheat protection circuit 36 is input into the current-voltage control circuit 23.

The low voltage malfunction suppressor circuit 37 prevents the power MISFET 9 from malfunctioning if the power supply voltage VB is less than a predetermined value. The low voltage malfunction suppressor circuit 37 is connected to the current-voltage control circuit 23. A signal generated by the low voltage malfunction suppressor circuit 37 is input into the current-voltage control circuit 23.

The gate control circuit 25 controls an ON state and an OFF state of the power MISFET 9 and an ON state and an OFF state of the sensor MISFET 21. The gate control circuit 25 is connected to the gate of the current-voltage control circuit 23, to the protection circuit 24, to the gate of the power MISFET 9, and to the gate of the sensor MISFET 21.

In accordance with an electric signal emitted from the current-voltage control circuit 23 and in accordance with an electric signal emitted from the protection circuit 24, the gate control circuit 25 generates a plurality of kinds of gate control signals according to the number of the gate control wirings 17. The plurality of kinds of gate control signals are each input into the gate of the power MISFET 9 and into the gate of the sensor MISFET 21 through the gate control wiring 17.

In detail, the gate control circuit 25 includes an oscillation circuit 38, a charge pump circuit 39, and the driving signal output circuit 40. The oscillation circuit 38 oscillates in accordance with an electric signal emitted from the current-voltage control circuit 23, and generates a predetermined electric signal. An electric signal generated by the oscillation circuit 38 is input into the charge pump circuit 39. The charge pump circuit 39 boosts an electric signal emitted from the oscillation circuit 38. The electric signal boosted by the charge pump circuit 39 is input into the driving signal output circuit 40.

The driving signal output circuit 40 generates a plurality of kinds of gate control signals in accordance with an electric signal emitted from the charge pump circuit 39 and in accordance with an electric signal emitted from the protection circuit 24 (in detail, overcurrent protection circuit 34). The plurality of kinds of gate control signals are input into the gate of the power MISFET 9 and into the gate of the sensor MISFET 21 through the gate control wiring 17. The sensor MISFET 21 and the power MISFET 9 are simultaneously controlled by the gate control circuit 25.

The active clamp circuit 26 protects the power MISFET 9 from a counter electromotive force. The active clamp circuit 26 is connected to the drain electrode 11, to the gate of the power MISFET 9, and to the gate of the sensor MISFET 21. The active clamp circuit 26 may include a plurality of diodes.

The active clamp circuit 26 may include a plurality of diodes that are bias-connected to each other. The active clamp circuit 26 may include a plurality of diodes that are reverse-bias-connected to each other. The active clamp circuit 26 may include a plurality of diodes that are bias-connected to each other and a plurality of diodes that are reverse-bias-connected to each other.

The plurality of diodes may include a pn junction diode, or may include a Zener diode, or may include both a pn junction diode and a Zener diode. The active clamp circuit 26 may include a plurality of Zener diodes that are bias-connected to each other. The active clamp circuit 26 may include a Zener diode and a pn junction diode that are reverse-bias-connected to each other.

The current detection circuit 27 detects an electric current flowing through the power MISFET 9 and through the sensor MISFET 21. The current detection circuit 27 is connected to the protection circuit 24, to the abnormality detection circuit 29, to the source of the power MISFET 9, and to the source of the sensor MISFET 21. The current detection circuit 27 generates a current detection signal in accordance with an electric signal generated by the power MISFET 9 and in accordance with an electric signal generated by the sensor MISFET 21. The current detection signal is input into the abnormality detection circuit 29.

The power source reverse-connection protection circuit 28 protects the current-voltage control circuit 23, the power MISFET 9, etc., from a reverse voltage when the power source is reverse-connected. The power source reverse-connection protection circuit 28 is connected to the reference voltage electrode 14 and to the current-voltage control circuit 23.

The abnormality detection circuit 29 monitors the voltage of the protection circuit 24. The abnormality detection circuit 29 is connected to the current-voltage control circuit 23, to the protection circuit 24, and to the current detection circuit 27. The abnormality detection circuit 29 generates an abnormality detection signal according to the voltage of the protection circuit 24, and outputs this signal to the outside if an abnormality (e.g., variation in voltage) occurs in any one of the overcurrent protection circuit 34, the load-open detection circuit 35, the overheat protection circuit 36, and the low voltage malfunction suppressor circuit 37.

In detail, the abnormality detection circuit 29 includes a first multiplexer circuit 41 and a second multiplexer circuit 42. The first multiplexer circuit 41 includes two input portions, one output portion, and one selection control input portion. The protection circuit 24 and the current detection circuit 27 are each connected to the input portion of the first multiplexer circuit 41. The second multiplexer circuit 42 is connected to the output portion of the first multiplexer circuit 41. The current-voltage control circuit 23 is connected to the selection control input portion of the first multiplexer circuit 41.

The first multiplexer circuit 41 generates an abnormality detection signal in accordance with an electric signal emitted from the current-voltage control circuit 23, in accordance with a voltage detection signal emitted from the protection circuit 24, and in accordance with a current detection signal emitted from the current detection circuit 27. The abnormality detection signal generated by the first multiplexer circuit 41 is input into the second multiplexer circuit 42.

The second multiplexer circuit 42 includes two input portions and one output portion. The output portion of the second multiplexer circuit 42 and the ENABLE electrode 15 are each connected to the input portion of the second multiplexer circuit 42. The SENSE electrode 16 is connected to the output portion of the second multiplexer circuit 42.

If the MCU is connected to the ENABLE electrode 15 and if the resistor is connected to the SENSE electrode 16, an ON signal is input from the MCU into the ENABLE electrode 15, and an abnormality detection signal is taken out from the SENSE electrode 16. The abnormality detection signal is transformed to an electric signal by means of the resistor connected to the SENSE electrode 16. An abnormal state of the semiconductor device 1 is detected on the basis of this electric signal.

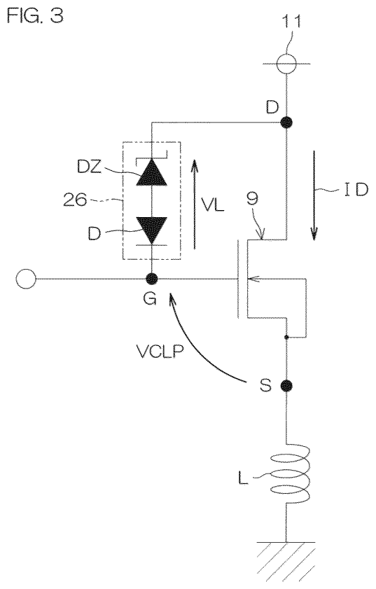

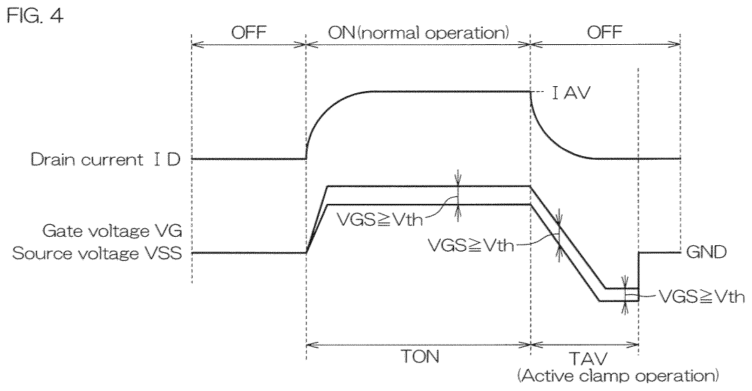

FIG. 3 is a circuit diagram shown to describe an active clamp operation of the semiconductor device 1 shown in FIG. 1. FIG. 4 is a waveform chart of a main electric signal of the circuit diagram shown in FIG. 3.

Here, a normal operation and an active clamp operation of the semiconductor device 1 will be described by use of a circuit example in which an inductive load L is connected to the power MISFET 9. A device using a coil, such as solenoid, motor, transformer, and relay, is shown as an example of the inductive load L. The inductive load L is referred to also as an L load.

Referring to FIG. 3, the source of the power MISFET 9 is connected to the inductive load L. The drain of the power MISFET 9 is electrically connected to the drain electrode 11. The gate and the drain of the power MISFET 9 are connected to the active clamp circuit 26. In this circuit example, the active clamp circuit 26 includes Zener diodes DZ the number of which is m (m is a natural number) and pn junction diodes D the number of which is n (n is a natural number). The pn junction diode D is reverse-bias-connected to the Zener diode DZ.

Referring to FIG. 3 and FIG. 4, the power MISFET 9 is switched from an OFF state to an ON state when the ON signal Von is input into the gate of the power MISFET 9 being in an OFF state (normal operation). The ON signal Von has a voltage that is equal to or more than the gate threshold voltage Vth (Vth≤Von). The power MISFET 9 is kept in an ON state only during a predetermined ON time TON.

A drain current ID begins to flow from the drain to the source of the power MISFET 9 when the power MISFET 9 is switched to an ON state. The drain current ID increases from a zero to a predetermined value, and reaches a saturated state. The inductive load L accumulates inductive energy as a result of an increase in the drain current ID.

The power MISFET 9 is switched from an ON state to an OFF state when the OFF signal Voff is input into the gate of the power MISFET 9. The OFF signal Voff has a voltage (Voff<Vth) less than the gate threshold voltage Vth. The OFF signal Voff may be a reference voltage (for example, ground voltage).

The inductive energy of the inductive load L is applied to the power MISFET 9 as a counter electromotive force at a transition time at which the power MISFET 9 is switched from the ON state to the OFF state. Hence, the power MISFET 9 reaches an active clamp state (active clamp operation). A source voltage VSS rapidly decreases to a negative voltage less than the reference voltage (ground voltage) when the power MISFET 9 reaches the active clamp state.

At this time, the source voltage VSS is limited to a voltage (VSS≥ VB−VL−VCLP) equal to or more than a voltage obtained by subtracting a limit voltage VL and a clamp-on voltage VCLP from the power supply voltage VB as a result of the operation of the active clamp circuit 26.

In other words, a drain voltage VDS between the drain and the source of the power MISFET 9 rapidly increases to a clamp voltage VDSSCL when the power MISFET 9 reaches the active clamp state. The clamp voltage VDSSCL is limited to a voltage (VDS≤VCLP+VL) equal to or less than a voltage obtained by adding the clamp-on voltage VCLP and the limit voltage VL by means of the power MISFET 9 and the active clamp circuit 26.

In this preferred embodiment, the limit voltage VL is the sum total (VL=m·VZ+n·VF) of a terminal-to-terminal voltage VZ of the Zener diode DZ and a terminal-to-terminal voltage VF of the pn junction diode in the active clamp circuit 26.

The clamp-on voltage VCLP is a positive voltage (i.e., a gate voltage VGS) applied to the gate-to-source of the power MISFET 9. The clamp-on voltage VCLP is equal to or more than the gate threshold voltage Vth (Vth≤VCLP). Therefore, the power MISFET 9 maintains the ON state in the active clamp state.

If the clamp voltage VDSSCL exceeds a maximum rated drain voltage VDSS (VDSS<VDSSCL), the power MISFET 9 leads to destruction. The power MISFET 9 is designed so that the clamp voltage VDSSCL becomes equal to or less than the maximum rated drain voltage VDSS (VDSSCL≤VDSS).

If the clamp voltage VDSSCL is equal to or less than the maximum rated drain voltage VDSS (VDSSCL≤VDSS), the drain current ID continuously flows from the drain of the power MISFET 9 toward the source of the power MISFET 9, and the inductive energy of the inductive load L is consumed (absorbed) in the power MISFET 9.

The drain current ID expends an active clamp time TAV, and decreases from a peak value IAV, which is a value immediately before the power MISFET 9 is turned off, to a zero. Hence, the gate voltage VGS becomes a reference voltage (for example, a ground voltage), and the power MISFET 9 is switched from the ON state to the OFF state.

An active clamp tolerance Eac of the power MISFET 9 is defined by a tolerance of the power MISFET 9 during an active clamp operation. In detail, the active clamp tolerance Eac is defined by the tolerance of the power MISFET 9 against a counter electromotive force that occurs because of the inductive energy of the inductive load L when the power MISFET 9 is changed from the ON state to the OFF state.

In still more detail, the active clamp tolerance Eac is defined by the tolerance of the power MISFET 9 against energy caused by the clamp voltage VDSSCL. For example, the active clamp tolerance Eac is represented by the formula Eac=(VL+VCLP)×ID×TAV by use of the limit voltage VL, the clamp-on voltage VCLP, the drain current ID, and the active clamp time TAV.

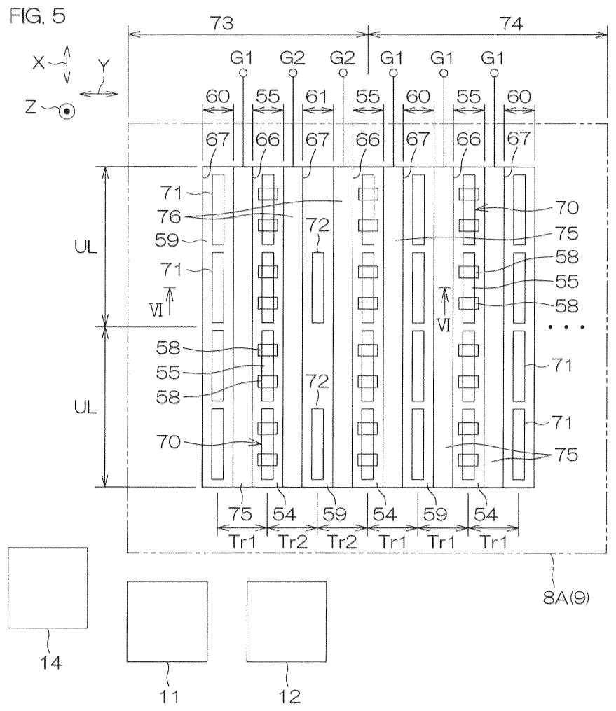

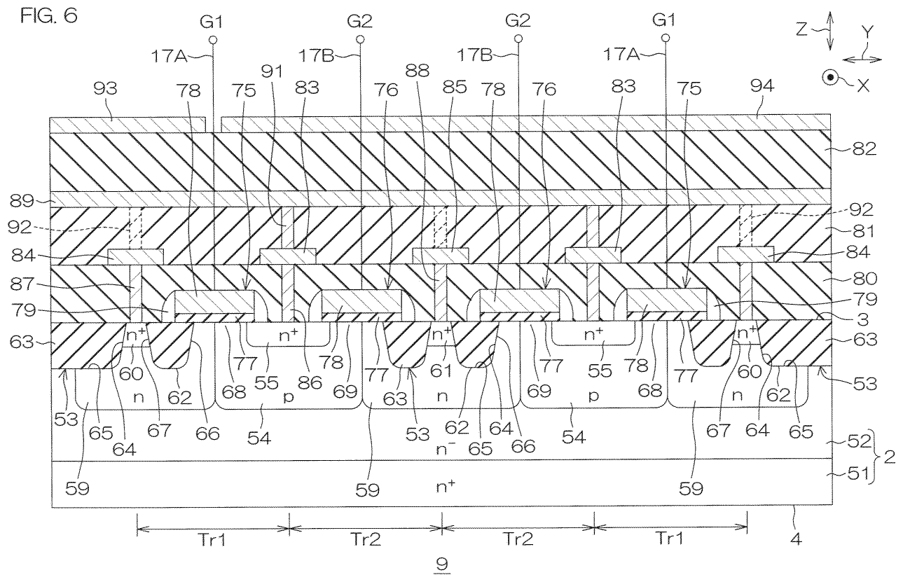

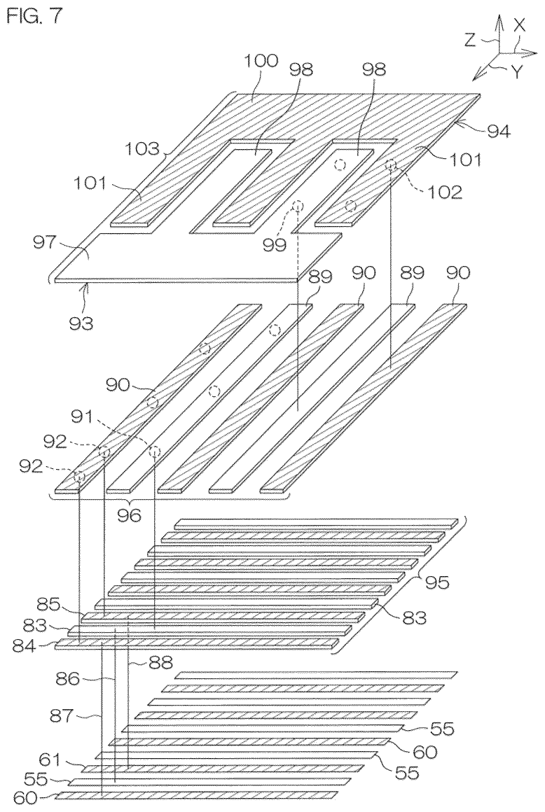

FIG. 5 is a schematic plan view shown by enlarging a part of the element region 8A of FIG. 1. For clarity, in FIG. 5, a state is shown in which the plurality of interlayer insulation layers 80, 81, 82 and a plurality of wiring layers have been removed. Also, in FIG. 5, the symbol “ . . . ” represents that continuously-arrayed transistor cells are omitted. FIG. 6 is a schematic perspective view showing a wiring structure of a transistor of FIG. 5. FIG. 7 is a view showing a cross section of line VII-VII of FIG. 5.

In this preferred embodiment, the semiconductor chip 2 has a layered structure including an n⁺-type semiconductor substrate 51 and an n-type epitaxial layer 52. The second principal surface 4 of the semiconductor chip 2 is formed by the semiconductor substrate 51. The first principal surface 3 of the semiconductor chip 2 is formed by the epitaxial layer 52. The end surfaces 5A to 5D of the semiconductor chip 2 are formed by the semiconductor substrate 51 and the epitaxial layer 52.

The epitaxial layer 52 has an n-type impurity concentration less than the n-type impurity concentration of the semiconductor substrate 51. The n-type impurity concentration of the semiconductor substrate 51 may be not less than 1×10¹⁸ cm⁻³ and not more than 1×10²⁰ cm⁻³. The n-type impurity concentration of the epitaxial layer 52 may be not less than 1×10¹⁵ cm⁻³ and not more than 1×10¹⁸ cm⁻³.

The epitaxial layer 52 has a thickness less than the thickness of the semiconductor substrate 51. The thickness of the semiconductor substrate 51 may be not less than 50 μm and not more than 450 μm. The thickness of the semiconductor substrate 51 may be not less than 50 μm and not more than 150 μm, not less than 150 μm and not more than 250 μm, not less than 250 μm and not more than 350 μm, or not less than 350 μm and not more than 450 μm. It is possible to reduce the resistance value by reducing the thickness of the semiconductor substrate 51. The thickness of the semiconductor substrate 51 is adjusted by grinding. In this case, the second principal surface 4 of the semiconductor chip 2 may be a ground surface having ground traces.

Preferably, the thickness of the epitaxial layer 52 is 1/10 or less of the thickness of the semiconductor substrate 51. The thickness of the epitaxial layer 52 may be not less than 5 μm and not more than 20 μm. The thickness of the epitaxial layer 52 may be not less than 5 μm and not more than 10 μm, not less than 10 μm and not more than 15 μm, or not less than 15 μm and not more than 20 μm. Preferably, the thickness of the epitaxial layer 52 is not less than 5 μm and not more than 15 μm.

In the element region 8A, the semiconductor device 1 may include a trench insulation structure 53, a body region 54, a source region 55, a body contact region 58, a drift region 59, a first drain region 60, and a second drain region 61.

In this preferred embodiment, the trench insulation structure 53 includes a trench 62 formed in the epitaxial layer 52 and a buried insulator 63 buried in the trench 62.

The trench 62 has a side surface 64 and a bottom surface 65. The side surface 64 of the trench 62 may be a surface perpendicular to the first principal surface 3, and may be a surface inclined with respect to the first principal surface 3 as shown in FIG. 6. The trench 62 may have a tapered shape whose width becomes narrower in proportion to an approach to the bottom surface 65 from the first principal surface 3 in the third direction Z in a cross-sectional view.

The buried insulator 63 may be, for example, silicon oxide (SiO₂), silicon nitride (SiN), or the like. In this preferred embodiment, the buried insulator 63 is made of silicon oxide. The trench insulation structure 53 may be referred to as an STI (Shallow Trench Isolation) as a general designation.

The trench insulation structure 53 has a first opening 66 and a second opening 67. The first opening 66 is formed in a rectangular shape longitudinal along the first direction X in a plan view, and exposes the source region 55. The second opening 67 includes a pair of second openings 67 between which the first opening 66 is sandwiched in the first direction X. Each of the second openings 67 is formed in a rectangular shape longitudinal along the second direction Y in a plan view, and exposes the first drain region 60 and the second drain region 61 independently of each other.

The body region 54 is formed at a surficial portion of the epitaxial layer 52, and is electrically connected to the epitaxial layer 52. The body region 54 is formed in an inward region of the first opening 66 that is at a distance from the trench insulation structure 53. The body region 54 is physically away inwardly from an inner peripheral edge of the first opening 66 in the second direction Y. Referring to FIG. 5, the body region 54 is formed to extend in the first direction X. In this preferred embodiment, the body region 54 is a p-type semiconductor region. The body region 54 has an impurity concentration of, for example, 1×10¹⁷ cm⁻³ to 1×10¹⁸ cm⁻³. Also, the depth of the body region 54 is deeper than the position of a bottom portion of the trench insulation structure 53, and may be, for example, 0.5 μm to 4.0 μm.

The source region 55 and the body contact region 58 are formed at a surficial portion of the body region 54, and are electrically connected to the body region 54. The source region 55 and the body contact region 58 are physically away inwardly from an outer peripheral edge of the body region 54 in the second direction Y, and are formed in an inward region of the body region 54. A region that is interposed between the outer peripheral edge of the body region 54 and an outer peripheral edge of the source region 55 and that consists of the body region 54 is a channel region 68 and a channel region 69 in each of which a channel is formed when an appropriate voltage is applied to a first planar gate structure 75 (described later) and to a second planar gate structure 76 (described later). The channel regions 68 and 69 include a first channel region 68 of the first transistor Tr1 and a second channel region 69 of the second transistor Tr2.

Referring to FIG. 5, the source region 55 and the body contact region 58 are alternately formed along the second direction Y as a plurality of source regions and as a plurality of body contact regions, respectively. The source region 55 and the body contact region 58 adjoining each other are contiguous to each other. In FIG. 5, groups (source units 70) each of which consists of the single source region 55 having a rectangular shape in a plan view and two body contact regions 58 formed at a distance from each other in a halfway portion in the longitudinal direction of the source region 55 are arrayed at a distance from each other along the first direction X. The number of the body contact regions 58 included in each of the source units 70 is not limited to two, and is merely required to be one or more. Also, one source region 55 that extends continuously and long may be formed without dividing the source region 55 into the plurality of source units 70, and the plurality of body contact regions 58 may be arrayed along the longitudinal direction of this source region 55. The body contact region 58 has a structure having a bottom portion that passes through the source region 55 from the first principal surface 3 in the third direction Z and that reaches the body region 54 although the cross-sectional structure of the body contact region 58 is not shown.

The drift region 59 is formed at the surficial portion of the epitaxial layer 52, and is electrically connected to the epitaxial layer 52. The drift region 59 is formed such that the drift region 59 straddle between the first and second openings 66 and 67 of the trench insulating structure 53, and is exposed from both the first opening 66 and the second opening 67. Referring to FIG. 5, the drift region 59 is formed to extend in the first direction X along the body region 54. Also, the drift region 59 may be contiguous to the body region 54 in the first opening 66.

In this preferred embodiment, the drift region 59 is an n-type semiconductor region, and has an impurity concentration higher than the epitaxial layer 52. The drift region 59 has an impurity concentration of, for example, 1×10¹⁷ cm⁻³ to 1×10¹⁸ cm⁻³. Also, the depth of the drift region 59 is deeper than the position of the bottom portion of the trench insulation structure 53, and may be, for example, 0.5 μm to 4.0 μm.

The first drain region 60 and the second drain region 61 are formed at a surficial portion of the drift region 59, and are electrically connected to the drift region 59. The first drain region 60 and the second drain region 61 are at a distance from the body region 54 in the second direction Y, and are exposed from the second opening 67 of the trench insulation structure 53. In this preferred embodiment, each of the first and second drain regions 60 and 61 is an n⁺-type semiconductor region, and has an impurity concentration higher than the drift region 59. Each of the first and second drain regions 60 and 61 has an impurity concentration of, for example, 1×10¹⁹ cm⁻³ to 5×10²¹ cm⁻³. Also, the depth of each of the first and second drain regions 60 and 61 may be, for example, 0.2 μm to 2.0 μm. For example, each of the first and second drain regions 60 and 61 may have the same depth as the source region 55.

Referring to FIG. 5, the first drain region 60 includes a plurality of first drain units 71 arrayed at a distance from each other along the first direction X. For example, two first drain units 71 are formed per unit length UL of FIG. 5. The number of the first drain units 71 for each unit length UL is not particularly limited. Likewise, the second drain region 61 includes a plurality of second drain units 72 arrayed at a distance from each other along the first direction X. Each of the second drain units 72 has the same planar shape as each of the first drain units 71, and has the same plane area as each of the first drain units 71. For example, one second drain unit 72 is formed per unit length UL of FIG. 5. The number of the second drain units 72 for each unit length UL is not limited to a specific number. Also, each of the first and second drain units 71 and 72 may have the same plane area as the source unit 70.

As thus described, in this preferred embodiment, the number of the second drain units 72 is less than the number of the first drain units 71 per unit length UL in the first direction X. For example, in the first drain region 60, the first drain units 71 are linearly arrayed along the first direction X with regularly fixed intervals between the first drain units 71. In the second drain region 61, the second drain units 72 are arrayed with an arrangement pattern in which some of the first drain units 71 of the first drain region 60 have been thinned out. Hence, a structure is formed in which at least one of the first drain units 71 faces the second drain unit 72 in the second direction Y and in which the remaining ones of the first drain units 71 do not face the second drain unit 72 in the second direction Y. Also, the first drain units 71 face the source units 70 in the second direction Y on a one-to-one basis.

The plane area of the first drain unit 71 and the plane area of the second drain unit 72 are the same as each other, and therefore, per unit length UL in the first direction X, the ratio of the area occupancy of the second drain region 61 to the area occupancy of the drift region 59 is smaller than the ratio of the area occupancy of the first drain region 60 to the area occupancy of the drift region 59. For example, the ratio of the area occupancy of the second drain region 61 may be equal to or less than 50% of the ratio of the area occupancy of the first drain region 60.

The first transistor Tr1 is formed between the first drain region 60 and the source region 55, and the second transistor Tr2 is formed between the second drain region 61 and the source region 55. The first transistor Tr1 and the second transistor Tr2 may share the source region 55. Therefore, the first and second drain regions 60 and 61 may adjoin each other with the common source region 55 between the first and second drain regions 60 and 61 in the second direction Y.

The first transistor Tr1 and the second transistor Tr2 are arrayed with a stripe pattern that extends along the first direction X. Specific limitations are not imposed on the arrangement of both the first transistor Tr1 and the second transistor Tr2 with this stripe pattern. Preferably, when the first element region 8A is divided into a first region 73 relatively closer to the reference voltage electrode 14 and a second region 74 farther from the reference voltage electrode 14 than the first region 73, the second transistor Tr2 is formed at least in the first region 73.

The first planar gate structure 75 and the second planar gate structure 76 are formed at the first principal surface 3. The first planar gate structure 75 is a gate structure for the first transistor Tr1. The first planar gate structure 75 is formed between the source region 55 and the first drain region 60, and covers the first channel region 68. The second planar gate structure 76 is a gate structure for the second transistor Tr2. The second planar gate structure 76 is formed between the source region 55 and the second drain region 61, and covers the second channel region 69.

Referring to FIG. 5, the first planar gate structure 75 and the second planar gate structure 76 are each formed in a linear shape extending along the first direction X while adjoining each other. Hence, the stripe-shaped gate structure is formed as a whole regardless of the position of the first planar gate structure 75 and the position of the second planar gate structure 76.

The first planar gate structure 75 and the second planar gate structure 76 include a gate insulation film 77 and a gate electrode 78 that are stacked in that order from the first main surface 3 side. The gate insulation film 77 may include a silicon oxide film. Preferably, the gate insulation film 77 includes a silicon oxide film made of an oxide of the semiconductor chip 2. Preferably, the gate electrode 78 includes conductive polysilicon. Preferably, the gate electrode 78 includes conductive polysilicon into which impurities have been introduced. The gate electrode 78 may have an n-type conductivity type, or may have a p-type conductivity type. A sidewall 79 is formed around the gate electrode 78. The sidewall 79 is continuously formed over the entirety of a periphery of the gate electrode 78 such that the sidewall 79 covers a side surface of the gate electrode 78. The sidewall 79 may be, for example, silicon oxide (SiO₂), silicon nitride (SiN), or the like.

The first gate control wiring 17A is electrically connected to the gate electrode 78 (first gate electrode) of the first planar gate structure 75. The second gate control wiring 17B is electrically connected to the gate electrode 78 (second gate electrode) of the second planar gate structure 76.

Referring to FIG. 6, a plurality of interlayer insulating layers 80, 81, and 82 are formed on the first principal surface 3 such that the plurality of interlayer insulating layers 80, 81, and 82 cover the first planar gate structure 75 and the second planar gate structure 76. The interlayer insulation layers 80, 81, and 82 are made of, for example, silicon oxide. The interlayer insulation layers 80, 81, and 82 include a first interlayer insulation layer 80, a second interlayer insulation layer 81, and a third interlayer insulation layer 82. The first interlayer insulation layer 80 is formed at the first principal surface 3, and the second interlayer insulation layer 81 is formed on the first interlayer insulation layer 80, and the third interlayer insulation layer 82 is formed on the second interlayer insulation layer 81.

A first source wiring 83, a first-1 drain wiring 84, and a first-2 drain wiring 85, which are covered with the second interlayer insulation layer 81, are formed at the first interlayer insulation layer 80. The first source wiring 83, the first-1 drain wiring 84, and the first-2 drain wiring 85 are connected to the source region 55, the first drain region 60, and the second drain region 61 through a first source via 86, a first-1 drain via 87, and a first-2 drain via 88, respectively.

A second source wiring 89 and a second drain wiring 90 (see FIG. 7), which are covered with the third interlayer insulation layer 82, are formed at the second interlayer insulation layer 81. The second source wiring 89 is connected to the first source wiring 83 through a second source via 91. The second drain wiring 90 is connected to both the first-1 drain wiring 84 and the first-2 drain wiring 85 through a second drain via 92.

A third source wiring 93 and a third drain wiring 94 are formed at the third interlayer insulation layer 82. The third source wiring 93 is connected to the second source wiring 89 through a third source via 99 (see FIG. 7). Also, the third source wiring 93 is connected to the source electrode 12 through a wiring (not shown). The third drain wiring 94 is connected to the second drain wiring 90 through a third drain via 102 (see FIG. 7). Also, the third drain wiring 94 is connected to the drain electrode 11 through a wiring (not shown).

Referring to FIG. 7, a description will be added concerning a spatial structure of a plurality of wiring layers (source wiring and drain wiring). In FIG. 7, the wiring layer of the drain is hatched.

The first source wiring 83, the first-1 drain wiring 84, and the first-2 drain wiring 85 are formed in linear shapes extending along the first direction X in regions directly above the source region 55, the first drain region 60, and the second drain region 61, respectively. The first source wiring 83, the first-1 drain wiring 84, and the first-2 drain wiring 85 are arrayed alternately at a distance from each other along the second direction Y, and form a stripe-shaped first wiring layer 95 as a whole. For clarity, only one connection state between the source region 55 and the first source wiring 83, only one connection state between the first drain region 60 and the first-1 drain wiring 84, and only one connection state between the second drain region 61 and the first-2 drain wiring 85 are shown in FIG. 7, and the remaining connection states are omitted.

The second source wiring 89 and the second drain wiring 90 are formed in a linear shape extending along the second direction Y. For example, the second source wiring 89 and the second drain wiring 90 are arrayed alternately at a distance from each other along the first direction X, and form a stripe-shaped second wiring layer 96 as a whole. Hence, the stripe pattern of the second wiring layer 96 crosses the stripe pattern of the first wiring layer 95. In this preferred embodiment, the stripe pattern of the first wiring layer 95 and the stripe pattern of the second wiring layer 96 perpendicularly intersect each other.

The second source via 91 and the second drain via 92 are connected to the second source wiring 89 and the second drain wiring 90 at the mutually deviated positions along the second direction Y. For clarity, only one connection state between the first source wiring 83 and the second source wiring 89 and only one connection state of the first-1, first-2 drain wirings 84, 85 and the second drain wiring 90 are shown in FIG. 7, and the remaining connection states are omitted.

The third source wiring 93 has a source base portion 97 that crosses the second source wirings 89 and the second drain wirings 90 along the first direction X and a source lead-out portion 98 that is led out from the source base portion 97 onto the second source wiring 89. The source lead-out portion 98 is connected to the second source wiring 89 through the third source via 99. For clarity, only one connection state between the third source wiring 93 (source lead-out portion 98) and the second source wiring 89 is shown in FIG. 7, and the remaining connection states are omitted.

The third drain wiring 94 has a drain base portion 100 that crosses the second source wirings 89 and the second drain wirings 90 along the first direction X and a drain lead-out portion 101 that is led out from the drain base portion 100 onto the second drain wiring 90. The drain lead-out portion 101 is connected to the second drain wiring 90 through the third drain via 102. For clarity, only one connection state between the third drain wiring 94 (drain lead-out portion 101) and the third source wiring 93 is shown in FIG. 7, and the remaining connection states are omitted.

The third source wiring 93 and the third drain wiring 94 form a third wiring layer 103. The third source wiring 93 and the third drain wiring 94 are each formed in a comb-teeth manner. The third source wiring 93 and the third drain wiring 94 mesh together so that the comb-teeth-shaped source lead-out portion 98 and the comb-teeth-shaped drain lead-out portion 101 are alternately arrayed.

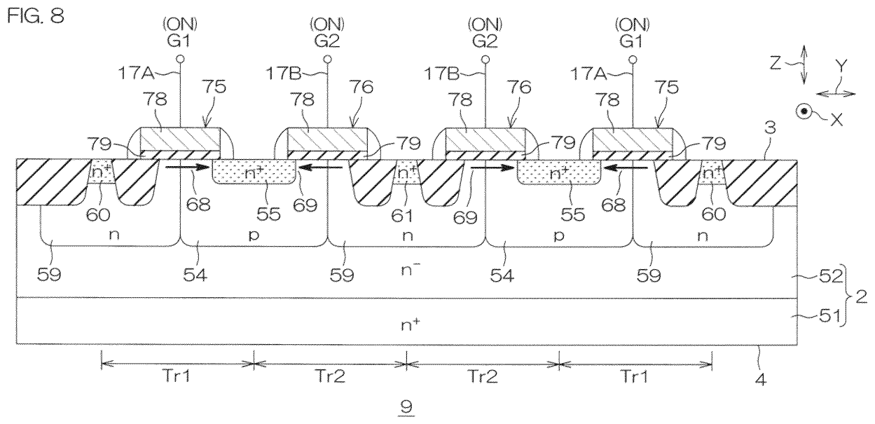

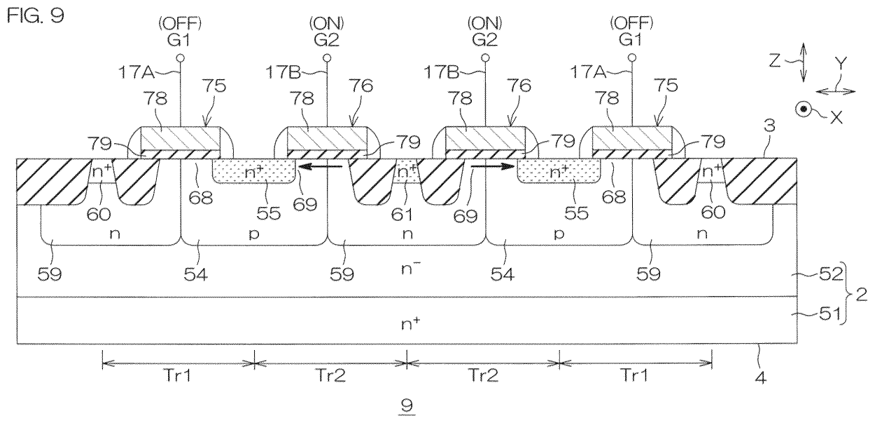

FIG. 8 is a view shown to describe a normal operation according to an example of the control of the semiconductor device 1 of FIG. 1. FIG. 9 is a view shown to describe an active clamp operation according to an example of the control of the semiconductor device 1 of FIG. 1. For descriptive convenience, only a configuration necessary for a description of a control example among configurations of FIG. 6 is shown in FIG. 8 and

FIG. 9.

Referring to FIG. 8, a first ON signal Von1 is input into the first gate control wiring 17A, and a second ON signal Von2 is input into the second gate control wiring 17B during the normal operation of the power MISFET 9.

The first ON signal Von1 and the second ON signal Von2 are each input from the control IC 10. The first ON signal Von1 and the second ON signal Von2 each have a voltage equal to or more than the gate threshold voltage Vth. The first ON signal Von1 and the second ON signal Von2 may each have a voltage equal to each other.

In this case, the gate electrodes 78 of both the first planar gate structure 75 and the second planar gate structure 76 reach an ON state. In other words, each of the gate electrodes 78 of both the first planar gate structure 75 and the second planar gate structure 76 functions as a gate electrode.

Hence, both the first channel region 68 and the second channel region 69 are controlled to be an ON state. In FIG. 8, the first and second drain regions 60 and 61 being in the ON state are shown by dot hatching. As a result, both the first transistor Tr1 and the second transistor Tr2 are driven (Full-ON control). A channel utilization ratio RU during the normal operation is 100%. The channel utilization ratio RU is a ratio of the first and second drain regions 60 and 61 controlled in the ON state of the first and second drain regions 60 and 61.

On the other hand, referring to FIG. 9, an OFF signal Voff is input into the first gate control wiring 17A, and a first clamp-on signal VCon1 is input into the second gate control wiring 17B during the active clamp operation of the power MISFET 9.

The OFF signal Voff and the first clamp-on signal VCon1 are each input from the control IC 10. The OFF signal Voff has a voltage (for example, reference voltage) less than the gate threshold voltage Vth. The first clamp-on signal VCon1 has a voltage equal to or more than the gate threshold voltage Vth. The first clamp-on signal VCon1 may have a voltage equal to or less than the voltage during the normal operation.

In this case, the gate electrode 78 of the first planar gate structure 75 reaches an OFF state, and the gate electrode 78 of the second planar gate structure 76 reaches an ON state. Hence, the first channel region 68 is controlled to be in an OFF state, and the second channel region 69 is controlled to be in an ON state. In FIG. 9, the first drain region 60 being in the OFF state is shown as an outlined region, and the second drain region 61 being in the ON state is shown as a dot-hatched region.

As a result, the first transistor Tr1 is controlled to be in the OFF state, whereas the second transistor Tr2 is controlled to be in the ON state (Half-ON control). Hence, the channel utilization ratio RU during the active clamp operation exceeds a zero, and becomes less than the channel utilization ratio RU during the normal operation. The channel utilization ratio RU during the active clamp operation is less than 50%. For example, if the layout of FIG. 5 is employed, the number of the first drain units 71 is fourteen, and the number of the second drain units 72 is two, and the number of the drain units is sixteen in total. During the active clamp operation, only the second drain unit 72 is in the ON state, and the channel utilization ratio RU is 12.5% (2/16×100%).

The semiconductor device 1 includes an IPD (Intelligent Power Device) formed at the semiconductor chip 2 as described above. The IPD includes the power MISFET 9 and the control IC 10 that controls the power MISFET 9. In detail, the power MISFET 9 includes the first transistor Tr1 and the second transistor Tr2. The control IC 10 individually controls the first transistor Tr1 and the second transistor Tr2.

In detail, the control IC 10 controls both the first transistor Tr1 and the second transistor Tr2 to be an ON state during the normal operation, and controls the first transistor Tr1 to be in an OFF state and the second transistor Tr2 to be in an ON state during the active clamp operation.

Therefore, it is possible to pass an electric current by use of both the first transistor Tr1 and the second transistor Tr2 during the normal operation. Hence, it is possible to reduce a sheet resistivity Ron·A (on-resistance). On the other hand, during the active clamp operation, it is possible to pass an electric current by use of the second transistor Tr2 in a state in which the first transistor Tr1 has been stopped, and therefore it is possible to consume (absorb) the counter electromotive force by means of the second transistor Tr2. This makes it possible to restrain a rapid temperature rise caused by the counter electromotive force, thus making it possible to improve the active clamp tolerance Eac. Therefore, it is possible to provide the semiconductor device 1 that is capable of achieving both of excellent sheet resistivity Ron·A and excellent active clamp tolerance Eac.

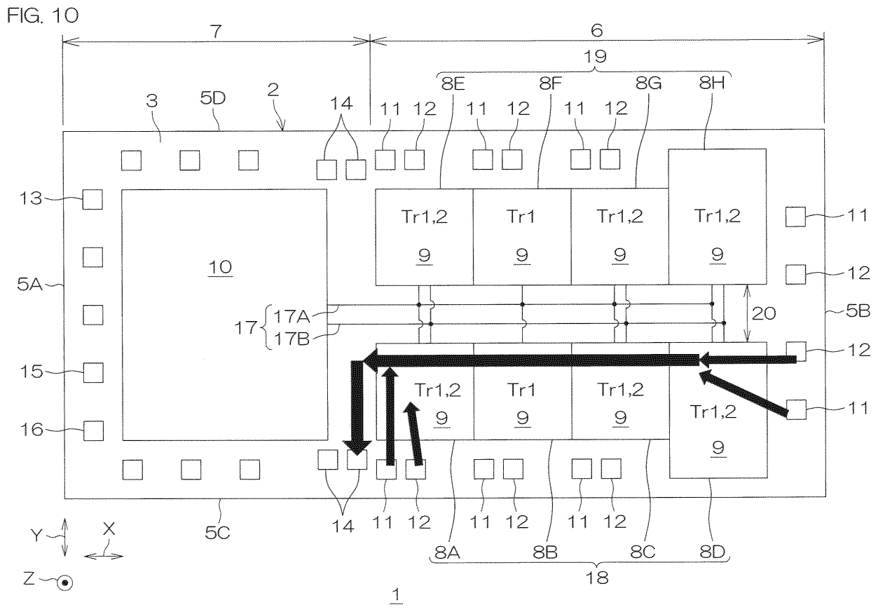

Also, the second transistor Tr2 is formed in the first region 73, which is relatively near the reference voltage electrode 14, of the element region 8A (the same applies to the other element regions 8B to 8H) as shown in FIG. 5. In the lateral type power MISFET 9 as in this preferred embodiment, it is conceivable that an electric current concentrates on the shortest distance from each of the output electrodes 11 and 12 to the reference voltage electrode 14 (ground terminal) as shown in FIG. 10. Therefore, it is possible to disperse an electric current flowing during the active clamp by selectively arranging the second transistor Tr2 in the first region 73.

Also, there is a case in which heat cannot be efficiently emitted near the second end surface 5B of the semiconductor chip 2 that is the furthest from the input region 7, and hence the active clamp tolerance Eac decreases as shown in FIG. 5. Therefore, it is possible to restrain a decrease in the active clamp tolerance Eac by arranging the second transistor Tr2 in the element regions 8D and 8H near the second end surface 5B.

The second transistor Tr2 may be arranged in all the element regions 8A to 8H, or has no need to be arranged in some of the element regions. In FIG. 5 and FIG. 10, only the first transistor Tr1 is arranged in the second element region 8B and in the sixth element region 8F.

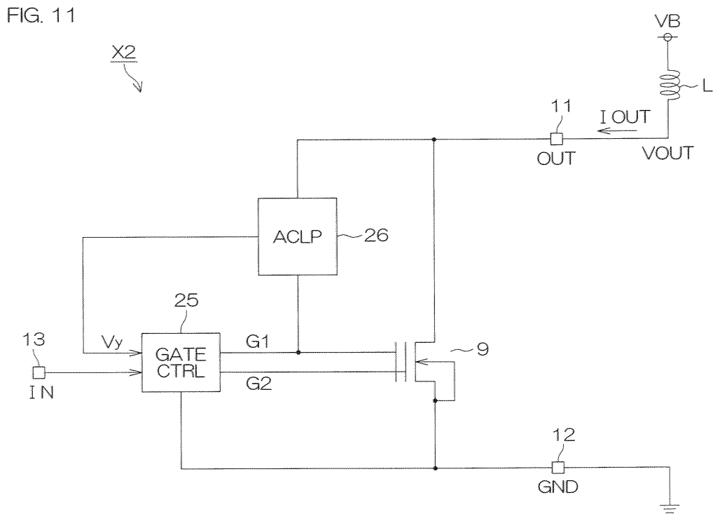

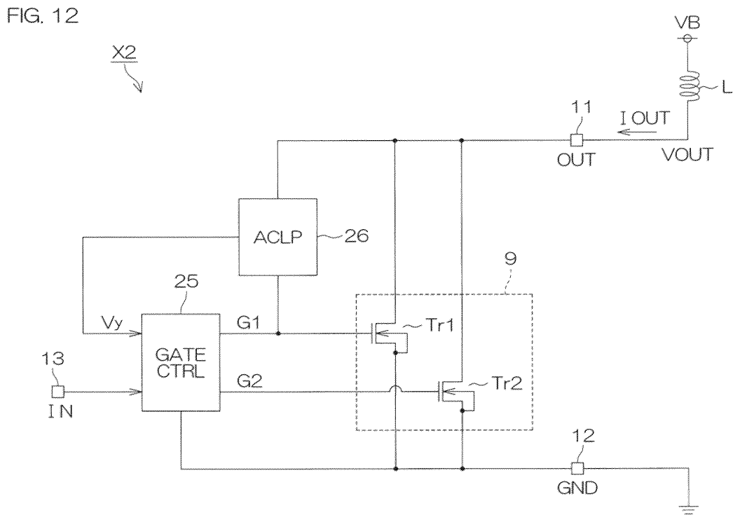

FIG. 11 is a block circuit diagram of the semiconductor device 1 (=an electric structure to perform the Half-ON control of the power MISFET 9 during the active clamp operation when the semiconductor device 1 is a low-side switch). FIG. 12 is an equivalent circuit diagram in which the power MISFET of FIG. 11 is represented as the first transistor Tr1 and as the second transistor Tr2.

A semiconductor device X2 (semiconductor device 1) has the drain electrode 11 (=output electrode OUT), the source electrode 12 (=ground electrode GND), the power MISFET 9, the gate control circuit 25, and the active clamp circuit 26. The same reference sign as above is assigned to each component mentioned above. Also, although only some components have been extracted and shown in this drawing for descriptive simplicity, it may be fundamentally understood that the same component as each component of the semiconductor device 1 (FIG. 1) mentioned is included in the semiconductor device X2.

The power MISFET 9 is a gate divided element whose structure has been described in detail in the aforementioned various preferred embodiments shown as examples. In other words, the power MISFET 9 can be equivalently represented as the first transistor Tr1 and as the second transistor Tr2 as shown in FIG. 5. From another viewpoint, it can be also understood that the first transistor Tr1 and the second transistor Tr2 that are controlled independently of each other are integrally formed as the power MISFET 9 that is a single gate divided element.

The gate control circuit 25 performs the gate control of the power MISFET 9 (then, the gate control of each of the first and second transistors Tr1 and Tr2). For example, gate signals G1 and G2 of each of the first and second transistors Tr1 and Tr2 are generated so that the gate control circuit 25 turns on both the first and second transistors Tr1 and Tr2 in an enable state (=corresponding to a first operational state) in which an external control signal IN input into the input electrode 13 is set as a high level, whereas the gate control circuit 25 turns off both the first and second transistors Tr1 and Tr2 in a disable state (=corresponding to a second operational state) in which the external control signal IN is set as a low level.

In the semiconductor device X2 used as a low-side switch, the external control signal IN is also used as a power supply voltage of the semiconductor device X2 in addition to functioning as an on/off control signal of the power MISFET 9.

Also, the gate control circuit 25 receives an internal node voltage Vy input from the active clamp circuit 26, and has a function to short the gate-to-source of the first transistor Tr1 before the active clamp circuit 26 operates (=before an output voltage VOUT is clamped) after shifting from an enable state (IN=H) to a disable state (IN=L), i.e., has a function to achieve the Half-ON control of the power MISFET 9 by completely stopping the first transistor Tr1 as G1=GND.

The active clamp circuit 26 is connected to the drain-to-gate of the second transistor Tr2, and the second transistor Tr2 is forcibly turned on (not brought into a full-off state) when the output voltage VOUT of the drain electrode 11 becomes an overvoltage, and, as a result, the drain-to-source voltage (=VOUT-GND) of each of the first and second transistors Tr1 and Tr2 is limited to a predetermined clamp voltage Vclp or less. The first transistor Tr1 does not contribute to the active clamp operation, and therefore the active clamp circuit 26 is not connected to the drain-to-gate thereof.

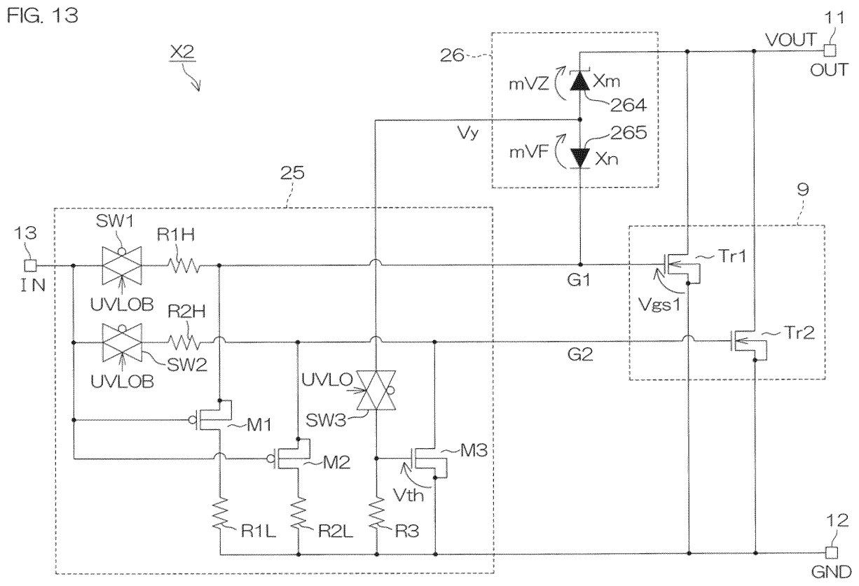

FIG. 13 is a circuit diagram showing a configuration example of the gate control circuit 25 and the active clamp circuit 26 of FIG. 11.

First, a configuration of the active clamp circuit 26 will be described in detail. The active clamp circuit 26 of this configuration example includes an m-stage Zener diode array 264 (for example, m=8) and an n-stage diode array 265 (for example, n=3).

The cathode of the Zener diode array 264 is connected to the drain electrode 11 (=corresponding to the output electrode OUT to which the output voltage VOUT is applied) together with the drain of each of the first and second transistors Tr1 and Tr2. The inductive load L, such as coil or solenoid, is connected to the drain electrode 11 as shown in FIG. 11 and FIG. 12 mentioned above. The anode of the Zener diode array 264 is connected to the anode of the diode array 265. The cathode of the diode array 265 is connected to the gate of the first transistor Tr1 (=application end of the gate signal G1).

Next, a configuration of the gate control circuit 25 will be described in detail. The gate control circuit 25 of this configuration example includes P-channel type MOS field effect transistors M1 and M2, an N-channel type MOS field effect transistor M3, resistors R1H and RIL, resistors R2H and R2L, a resistor R3, and switches SW1 to SW3.

The switch SW1 is connected to a place between the input electrode 13 and a first end of the resistor R1H (=corresponding to a first upper resistor), and is turned on/off in accordance with an inversion undervoltage detection signal UVLOB (=signal in which the logic level of an undervoltage detection signal UVLO has been reversed). In more detail, the switch SW1 is turned on when UVLOB=H (UVLO=L), and is turned off when UVLOB=L (UVLO=H).

The switch SW2 is connected to a place between the input electrode 13 and a first end of the resistor R2H (=corresponding to a second upper resistor), and is turned on/off in accordance with the inversion undervoltage detection signal UVLOB. In more detail, the switch SW2 is turned on when UVLOB=H (UVLO=L), and is turned off when UVLOB=L (UVLO=H).

The switch SW3 is connected to a place between an application end of the internal node voltage Vy (=for example, connection node between the Zener diode array 264 and the diode array 265) and a first end of the resistor R3 in the active clamp circuit 26, and is turned on/off in accordance with an undervoltage detection signal UVLO. In more detail, the switch SW3 is turned on when UVLO=H (UVLOB=L), and is turned off when UVLO=L (UVLOB=H). The application end of the internal node voltage Vy is not limited to the aforementioned one, and may use the anode voltage of, for example, any one among the n-stage diodes forming the diode array 265 as the internal node voltage Vy.

By the way, the logic level of each of both the undervoltage detection signal UVLO and the inversion undervoltage detection signal UVLOB is switched in accordance with a comparison result between the external control signal IN (=corresponding to the power supply voltage of the semiconductor device X2) and an undervoltage detection threshold value Vuvlo. In more detail, UVLO=H, and UVLOB=L (logic level when UVLO is detected) when IN<Vuvlo, and the switches SW1 and SW2 are turned off, and the switch SW3 is turned on. On the contrary, UVLO=L, and UVLOB=H (logic level when UVLO is released) when IN>Vuvlo, and the switches SW1 and SW2 are turned on, and the switch SW3 is turned off. As thus described, the switches SW1, SW2 and the switch SW3 are complementarily turned on/off.

A second end of the resistor R1H and the source and the back gate of the transistor M1 are each connected to the gate of the first transistor Tr1. The drain of the transistor M1 is connected to a first end of the resistor RIL (=corresponding to a first lower resistor). A second end of the resistor RIL is connected to the source electrode 12 (=corresponding to the ground electrode GND to which the ground voltage GND is applied). The gate of the transistor M1 is connected to the input electrode 13.

A second end of the resistor R2H and the source and the back gate of the transistor M2 are each connected to the gate of the second transistor Tr2. The drain of the transistor M2 is connected to a first end of the resistor R2L (=corresponding to a second lower resistor). A second end of the resistor R2L is connected to the source electrode 12 (=corresponding to a ground electrode GND). The gate of the transistor M2 is connected to the input electrode 13.

The drain of the transistor M3 is connected to the gate of the second transistor Tr2. The gate of the transistor M3 is connected to the first end of the resistor R3. The source and the back gate of the transistor M3 and a second end of the resistor R3 are connected to the source electrode 12.

The Half-ON control of the power MISFET 9 during the active clamp operation will be hereinafter described under the condition that a gate-to-source voltage of the first transistor Tr1 is designated as Vgs1, and a ON-threshold voltage of the transistor M3 is designated as Vth, and a breakdown voltage of the Zener diode array 264 is designated as mVZ, and a forward drop voltage of the diode array 265 is designated as nVF.

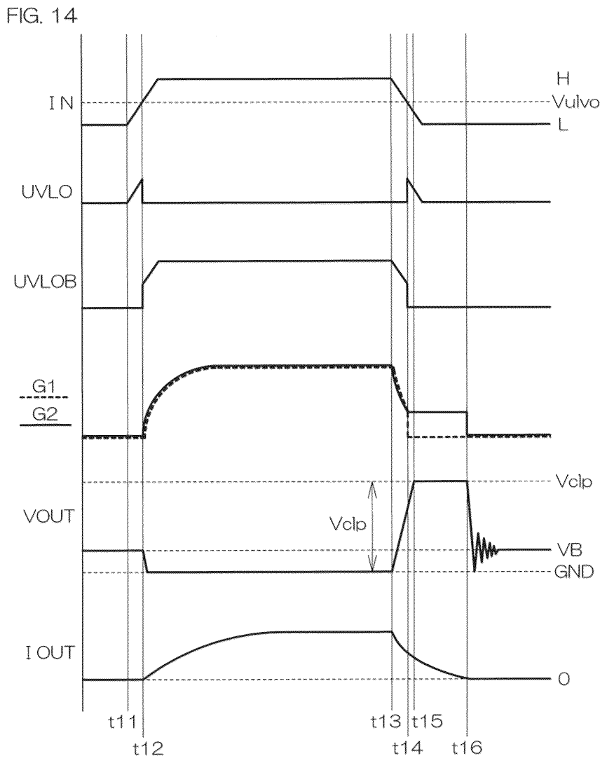

FIG. 14 is a timing chart showing an aspect in which the Half-ON control of the power MISFET 9 is performed during an active clamp operation in the semiconductor device X2, and an external control signal IN, an undervoltage detection signal UVLO and the inversion undervoltage detection signal UVLOB, a gate signal G1 (solid line), a gate signal G2 (broken line), an output voltage VOUT, and an output current IOUT are represented in order from the upper to the lower. In this drawing, the inductive load L is assumed as being connected to the drain electrode 11 (output electrode OUT).

The external control signal IN begins to change from a low level (=logic level when the power MISFET 9 is turned off) to a high level (=logic level when the power MISFET 9 is turned on) at time t11. However, IN<Vuvlo at this time point, and therefore UVLO=H, and UVLOB=L. Therefore, in the gate control circuit 25, the switches SW1 and SW2 are turned off, and the switch SW3 is turned on, and the gate signals G1 and G2 are maintained at the low level, and therefore both of the first and second transistors Tr1 and Tr2 remain off. As a result, the output current IOUT does not flow, and VOUT≈VB.

When IN>Vuvlo at time t12, UVLO=L, and UVLOB=H. Therefore, in the gate control circuit 25, the switches SW1 and SW2 are turned on, and the switch SW3 is turned off. At this time, the current path between the gate of each the first and second transistors Tr1 and Tr2 and the input electrode 13 becomes electrically conductive, and therefore the gate signals G1 and G2 rise in the high level, and both of the first and second transistors Tr1 and Tr2 are turned on. As a result, the output current IOUT begins to flow, and therefore the output voltage VOUT decreases to the vicinity of the ground voltage GND. This state corresponds to the Full-ON state of the power MISFET 9. The rate of rise (=slew rate when the switch is turned on) of each the gate signals G1 and G2 is enabled to be adjusted in accordance with a resistance value of each of the resistors R1H and R2H.

Also, the switch SW3 is in an OFF state, and therefore the node voltage Vy of the active clamp circuit 26 is not applied to the gate of the transistor M3, and The transistor M3 is not turned on without intention.

Thereafter, the external control signal IN begins to change from the high level to the low level at time t13. As a result, the transistors M1 and M2 are turned on, and the current path between the gate of each of the first and second transistors Tr1 and Tr2 and the source electrode 12 (=ground electrode GND) becomes electrically conductive, and therefore the gate signals G1 and G2 decrease, and the first and second transistors Tr1 and Tr2 change from ON to OFF. The rate of fall (=slew rate when the switch is turned off) of each of the gate signals G1 and G2 is enabled to be adjusted in accordance with the resistance value of each of the resistors R1L and R2L.

At this time, the inductive load L continues to pass the output current IOUT until energy stored during the ON time period of the power MISFET 9 is emitted. As a result, the output voltage VOUT rapidly rises to a voltage higher than the power supply voltage VB.

However, when the output voltage VOUT rises to the clamp voltage Vclp (=Vgs1+nVF+mVZ) at time t15, the second transistor Tr2 is turned on by the operation of the active clamp circuit 26 (not brought into a full-off state), and therefore the output current IOUT is electrically discharged through the second transistor Tr2. Therefore, the clamp voltage Vclp is limited to the output voltage VOUT or less. This active clamp operation is continuously performed until time t16 at which the energy stored in the inductive load L is completely discharged, and, as a result, the output current IOUT stops flowing.

On the other hand, when paying attention to the first transistor Tr1, IN<Vuvlo at time t14, and the switch SW3 is turned on when the undervoltage detection signal UVLO rises from the low level to the high level, and therefore a state is reached in which the node voltage Vy (>Vth) of the active clamp circuit 26 is applied to the gate of the transistor M3. Therefore, the transistor M3 is turned on, and the gate-to-source of the first transistor Tr1 is shorted (G1=VOUT). In other words, the first transistor Tr1 is completely stopped by the operation of the transistor M3 before the active clamp circuit 26 operates (before time t15). This state corresponds to the Half-ON state of the power MISFET 9.

As thus described, the channel utilization ratio RU during the active clamp operation (=time t15 to t16) exceeds a zero, and becomes less than the channel utilization ratio RU during the normal operation (=time t11 to t13) by performing switching from the Full-ON state to the Half-ON state.

Therefore, a characteristic channel ratio RC relatively increases during the normal operation (for example, RC=50%). Hence, the current path relatively increases, and therefore it is possible to reduce the sheet resistivity Ron·A (on-resistance). On the other hand, the characteristic channel ratio RC relatively decreases during the active clamp operation (for example, RC=25%). This makes it possible to restrain a rapid temperature rise caused by the counter electromotive force of the inductive load L, thus making it possible to improve the active clamp tolerance Eac.

Although the preferred embodiments of the present disclosure have been described, the present disclosure can be embodied in other modes.

For example, although an example was described in the aforementioned preferred embodiments in which the first conductivity type is an n-type and the second conductivity type is a p-type, the first conductivity type may be a p-type and the second conductivity type may be an n-type. A concrete configuration in this case can be obtained by replacing the p-type with the n-type and by replacing the n-type with the p-type in the foregoing description and in the accompanying drawings. Although the n-type is expressed as the “first conductivity type,” and the p-type is expressed as the “second conductivity type” as described in each of the aforementioned preferred embodiments, these are used to clarify the order of the description, and the n-type may be expressed as the “second conductivity type,” and the p-type may be expressed as the “first conductivity type.”

As described above, the preferred embodiments of the present disclosure are illustrative in all respects, and should not be construed limitedly, and are intended to include changes in all respects.

Features appended below can be extracted from this description and from the drawings.

### Appendix 1-1

A semiconductor device comprising:
a semiconductor chip that has a first principal surface and a second principal surface formed on a side opposite to the first principal surface;
an insulated gate type first transistor that is formed at the semiconductor chip and in which a first channel is formed in a horizontal direction along the first principal surface;
an insulated gate type second transistor that is formed at the semiconductor chip and in which a second channel is formed in the horizontal direction; and
a control wiring that is formed on the semiconductor chip such that the control wiring is electrically connected to the first transistor and to the second transistor and that transmits a control signal controlling the first transistor and the second transistor to reach an ON state during a normal operation and controlling the first transistor to reach an OFF state and the second transistor to reach an ON state during an active clamp operation.

### Appendix 1-2

The semiconductor device according to Appendix 1-1, wherein the control wiring includes a first control wiring electrically connected to the first transistor and a second control wiring electrically connected to the second transistor in a state of being electrically insulated from the first transistor.

### Appendix 1-3

The semiconductor device according to Appendix 1-1 or Appendix 1-2, comprising:
a first conductivity type drift region formed at a surficial portion of the first principal surface;
a second conductivity type body region formed at a surficial portion of the drift region; and
a first conductivity type source region formed at a surficial portion of the body region,
wherein the first transistor includes:
the source region;
a first drain region that is formed at the surficial portion of the drift region and that is formed on one side in the horizontal direction with respect to the source region; and
a first planar gate structure formed between the source region and the first drain region, and
wherein the second transistor includes:
the source region shared with the first transistor;
a second drain region that is formed at the surficial portion of the drift region and that is formed on another side in the horizontal direction with respect to the source region; and
a second planar gate structure formed between the source region and the second drain region.

### Appendix 1-4

The semiconductor device according to Appendix 1-3, wherein an area occupancy ratio of the second drain region is smaller than an area occupancy ratio of the first drain region per unit length in a direction intersecting a facing direction in which the first planar gate structure and the second planar gate structure face each other.

### Appendix 1-5

The semiconductor device according to Appendix 1-3 or Appendix 1-4, wherein the first drain region includes a plurality of first drain units having a first plane area, and
the second drain region includes a plurality of second drain units having a second plane area that is same as the first plane area, and
the second drain units are smaller in number than the first drain units per unit length in the direction intersecting the facing direction in which the first planar gate structure and the second planar gate structure face each other.

### Appendix 1-6

The semiconductor device according to Appendix 1-5, wherein at least one of the plurality of first drain units faces the second drain unit in the facing direction, and remaining ones of the plurality of first drain units do not face the second drain unit in the facing direction.

### Appendix 1-7

The semiconductor device according to any one of Appendix 1-3 to Appendix 1-6, wherein the first planar gate structure and the second planar gate structure are each formed in a linear shape extending along the first direction while adjoining each other.

### Appendix 1-8

The semiconductor device according to Appendix 1-6 or Appendix 1-7, comprising:
a first interlayer insulation layer formed on the semiconductor chip;
a first source wiring that extends along the first direction on the first interlayer insulation layer and that is electrically connected to the source region;
a first-1 drain wiring that extends along the first direction on the first interlayer insulation layer while adjoining the first source wiring and that is electrically connected to the first drain region;
a first-2 drain wiring that extends along the first direction on the first interlayer insulation layer while adjoining the first source wiring and that is electrically connected to the second drain region;
a second interlayer insulation layer formed on the first interlayer insulation layer such that the second interlayer insulating layer covers the first source wiring, the first-1 drain wiring, and the first-2 drain wiring;
a second source wiring that extends along a second direction intersecting the first direction on the second interlayer insulation layer and that is electrically connected to the first source wiring; and
a second drain wiring that extends along the second direction on the second interlayer insulation layer while adjoining the second source wiring and that is electrically connected to both the first-1 drain wiring and the first-2 drain wiring.

### Appendix 1-9

The semiconductor device according to Appendix 1-8, wherein the plurality of second source wirings and the plurality of second drain wirings are alternately arrayed along the first direction.

### Appendix 1-10

The semiconductor device according to Appendix 1-9, further comprising:
a third interlayer insulation layer formed on the second interlayer insulation layer such that the third interlayer insulating layer covers the second source wiring and the second drain wiring;
a third source wiring that is formed on the third interlayer insulation layer and that has a source base portion crossing the plurality of second source wirings and the plurality of second drain wirings along the first direction and a source lead-out portion led out from the source base portion onto the second source wiring; and
a third drain wiring that is formed on the third interlayer insulation layer and that has a drain base portion crossing the plurality of second source wirings and the plurality of second drain wirings along the first direction and a drain lead-out portion led out from the drain base portion onto the second drain wiring.

### Appendix 1-11

The semiconductor device according to any one of Appendix 1-1 to Appendix 1-10, wherein a plurality of element regions arrayed along the horizontal direction are formed at the first principal surface, and
both the first transistor and the second transistor are formed in at least one element region of the plurality of element regions.

### Appendix 1-12

The semiconductor device according to Appendix 1-11, wherein the plurality of element regions include an element region in which only the first transistor of the first transistor and the second transistor is formed.

### Appendix 1-13

The semiconductor device according to Appendix 1-11 or Appendix 1-12, wherein a control circuit region that transmits a control signal that controls the first transistor and the second transistor through the control wiring is formed at the first principal surface, and
the plurality of element regions are arrayed from the control circuit region toward an end surface surrounding the first principal surface and the second principal surface along the horizontal direction, and
the second transistor is formed in the element region that is closest to the end surface among the plurality of element regions.

### Appendix 1-14

The semiconductor device according to Appendix 1-13, wherein the semiconductor chip is formed in a quadrangular shape in a plan view so that the end surface has a first end surface, a second end surface facing the first end surface, a third end surface, and a fourth end surface facing the third end surface, and
the control circuit region is formed closer to the first end surface, and
the plurality of element regions are arrayed from the control circuit region toward the second end surface, and
the second transistor is formed in the element region that is closest to the second end surface among the plurality of element regions.

### Appendix 1-15

The semiconductor device according to Appendix 1-14, wherein the plurality of element regions include a plurality of first element region groups arrayed along the third end surface and a plurality of second element region groups arrayed along the fourth end surface, and
the control wiring extends from the control circuit region toward the second end surface in a region between the first element region group and the second element region group.

### Appendix 1-16

The semiconductor device according to any one of Appendix 1-11 to Appendix 1-15, comprising a ground terminal that is formed adjacent to the plurality of element regions and that is fixed at a ground potential,
wherein, in the one element region, the first transistor is formed in a first region relatively close to the ground terminal, and the second transistor is formed in a second region that is farther from the ground terminal than the first region.

1. A semiconductor device comprising:
a semiconductor chip that has a first principal surface and a second principal surface formed on a side opposite to the first principal surface;
an insulated gate type first transistor that is formed at the semiconductor chip and in which a first channel is formed in a horizontal direction along the first principal surface;
an insulated gate type second transistor that is formed at the semiconductor chip and in which a second channel is formed in the horizontal direction; and
a control wiring that is formed on the semiconductor chip such that the control wiring is electrically connected to the first transistor and to the second transistor and that transmits a control signal,
the control signal controlling the first transistor and the second transistor to reach an ON state during a normal operation,
the control signal controlling the first transistor to reach an OFF state and controlling the second transistor to reach an ON state during an active clamp operation.

2. The semiconductor device according to claim 1, wherein the control wiring includes a first control wiring electrically connected to the first transistor and a second control wiring electrically connected to the second transistor in a state of being electrically insulated from the first transistor.

3. The semiconductor device according to claim 1, comprising:
a first conductivity type drift region formed at a surficial portion of the first principal surface;
a second conductivity type body region formed at a surficial portion of the drift region; and
a first conductivity type source region formed at a surficial portion of the body region,
wherein the first transistor includes:
the source region;
a first drain region that is formed at the surficial portion of the drift region and that is formed on one side in the horizontal direction with respect to the source region; and
a first planar gate structure formed between the source region and the first drain region, and
wherein the second transistor includes:
the source region shared with the first transistor;
a second drain region that is formed at the surficial portion of the drift region and that is formed on another side in the horizontal direction with respect to the source region; and
a second planar gate structure formed between the source region and the second drain region.

4. The semiconductor device according to claim 3, wherein an area occupancy ratio of the second drain region is smaller than an area occupancy ratio of the first drain region per unit length in a direction intersecting a facing direction in which the first planar gate structure and the second planar gate structure face each other.

5. The semiconductor device according to claim 3, wherein the first drain region includes a plurality of first drain units having a first plane area, and
the second drain region includes a plurality of second drain units having a second plane area that is same as the first plane area, and
the second drain units are smaller in number than the first drain units per unit length in the direction intersecting the facing direction in which the first planar gate structure and the second planar gate structure face each other.

6. The semiconductor device according to claim 5, wherein at least one of the plurality of first drain units faces the second drain unit in the facing direction, and remaining ones of the plurality of first drain units do not face the second drain unit in the facing direction.

7. The semiconductor device according to claim 3, wherein the first planar gate structure and the second planar gate structure are each formed in a linear shape extending along the first direction while adjoining each other.

8. The semiconductor device according to claim 6, comprising:
a first interlayer insulation layer formed on the semiconductor chip;
a first source wiring that extends along the first direction on the first interlayer insulation layer and that is electrically connected to the source region;
a first-1 drain wiring that extends along the first direction on the first interlayer insulation layer while adjoining the first source wiring and that is electrically connected to the first drain region;
a first-2 drain wiring that extends along the first direction on the first interlayer insulation layer while adjoining the first source wiring and that is electrically connected to the second drain region;
a second interlayer insulation layer formed on the first interlayer insulation layer such that the second interlayer insulating layer covers the first source wiring, the first-1 drain wiring, and the first-2 drain wiring;
a second source wiring that extends along a second direction intersecting the first direction on the second interlayer insulation layer and that is electrically connected to the first source wiring; and
a second drain wiring that extends along the second direction on the second interlayer insulation layer while adjoining the second source wiring and that is electrically connected to both the first-1 drain wiring and the first-2 drain wiring.

9. The semiconductor device according to claim 8, wherein the plurality of second source wirings and the plurality of second drain wirings are alternately arrayed along the first direction.

10. The semiconductor device according to claim 9, further comprising:
a third interlayer insulation layer formed on the second interlayer insulation layer such that the third interlayer insulating layer covers the second source wiring and the second drain wiring;
a third source wiring that is formed on the third interlayer insulation layer and that has a source base portion crossing the plurality of second source wirings and the plurality of second drain wirings along the first direction and a source lead-out portion led out from the source base portion onto the second source wiring; and
a third drain wiring that is formed on the third interlayer insulation layer and that has a drain base portion crossing the plurality of second source wirings and the plurality of second drain wirings along the first direction and a drain lead-out portion led out from the drain base portion onto the second drain wiring.

11. The semiconductor device according to claim 1, wherein a plurality of element regions arrayed along the horizontal direction are formed at the first principal surface, and
both the first transistor and the second transistor are formed in at least one element region of the plurality of element regions.

12. The semiconductor device according to claim 11, wherein the plurality of element regions include an element region in which only the first transistor of the first transistor and the second transistor is formed.

13. The semiconductor device according to claim 11, wherein a control circuit region that transmits a control signal that controls the first transistor and the second transistor through the control wiring is formed at the first principal surface, and
the plurality of element regions are arrayed from the control circuit region toward an end surface surrounding the first principal surface and the second principal surface along the horizontal direction, and
the second transistor is formed in the element region that is closest to the end surface among the plurality of element regions.

14. The semiconductor device according to claim 13, wherein the semiconductor chip is formed in a quadrangular shape in a plan view so that the end surface has a first end surface, a second end surface facing the first end surface, a third end surface, and a fourth end surface facing the third end surface, and
the control circuit region is formed closer to the first end surface, and
the plurality of element regions are arrayed from the control circuit region toward the second end surface, and
the second transistor is formed in the element region that is closest to the second end surface among the plurality of element regions.

15. The semiconductor device according to claim 14, wherein the element regions include a plurality of first element region groups arrayed along the third end surface and a plurality of second element region groups arrayed along the fourth end surface, and
the control wiring extends from the control circuit region toward the second end surface in a region between the first element region group and the second element region group.

16. The semiconductor device according to claim 11, comprising a ground terminal that is formed adjacent to the element regions and that is fixed at a ground potential,
wherein, in the one element region, the first transistor is formed in a first region relatively close to the ground terminal, and the second transistor is formed in a second region that is farther from the ground terminal than the first region.
